(19) United States
(12) Patent Application Publication
(10) Pub. No.: US 2005/0238881 A1
(43) Pub. Date: Oct. 27, 2005

(54) Semiconductor assembly using dual-cure die attach adhesive

(76) Inventors: Kevin Harris Becker, Cerritos, CA (US); Harry Richard Kuder, Fullerton, CA (US)

Correspondence Address: Jane E. Gennaro;National Starch and Chemical, 10 Finderne Avenue, Bridgewater, NJ, 08807, US

(21) Appl. No.: 11/168,037

(22) Filed: Jun. 27, 2005

Related U.S. Application Data
(62) Division of application No. 10/016,844, filed on Dec. 14, 2001.

(51) Int. Cl. B32B 27/38; H01L 21/48

(52) U.S. Cl. 428/413; 438/106

(57) ABSTRACT

A semiconductor assembly comprising a semiconductor chip on a substrate is adhered to the substrate using a dual cure B-stageable adhesive comprising two chemical compositions, (i) a first composition comprising a curable monomeric or polymeric compound or resin and a curing initiator or curing agent for that compound or resin, and (ii) a second composition comprising a monomeric or polymeric compound or resin and a curing initiator or curing agent for that compound or resin, in which the curing temperatures or curing temperature ranges are sufficiently separated to allow the composition with the lower curing temperature, the first composition, to cure without curing the composition with the higher curing temperature, the second composition.

### FIELD OF THE INVENTION

This invention relates to B-stageable compositions suitable for use in attaching semiconductor chips to substrates. The compositions contain two separately curing chemistries.

### BACKGROUND OF THE INVENTION

In one type of semiconductor package, a semiconductor die or chip is electrically connected, and mechanically bonded with an adhesive, to a substrate. The substrate in turn is connected to other electronic devices or an outside power source. The fabrication can take place in a continuous series of steps, or the substrate can be prepared with the adhesive for the mechanical attach, and then held until a later time.

When the fabrication takes place in a continuous series of steps, the adhesive is deposited onto the substrate, the semiconductor chip contacted with the adhesive, and the adhesive cured by the application of heat, or heat and pressure. Suitable adhesives may be either solvent-free liquids and pastes, or solids. If in the form of liquid or paste, the adhesive is both cured and solidified by the application of heat.

If the fabrication process is to be interrupted after the deposition of the adhesive to the substrate and the final assembly held to a later time, the adhesive must be in a solidified form for successful storage. Solid adhesives provide the further advantages of minimal or no bleeding, and better control of bondline thickness and bondline tilt, the bondline being the interface between the chip and the adhesive.

For some semiconductor packaging applications, paste adhesives are preferred over film adhesives for process reasons, yet the bond-line and fillet control of solids are desired. In such a case, an adhesive known as a B-stageable adhesive may be used. If the starting adhesive material is a solid, the solid is dispersed or dissolved in a solvent to form a paste and the paste applied to the substrate. The adhesive is then heated to evaporate the solvent, leaving a solid, but uncured, adhesive on the substrate. If the starting adhesive material is a liquid or paste, the adhesive is dispensed onto the substrate and heated to partially cure the adhesive to a solid state. The application of heat at this stage in fabrication is termed B-staging, and the adhesive, B-stageable.

Although there are the advantages to solid adhesives mentioned above, there are also disadvantages. After B-staging and during storage, solid adhesives are prone to absorbing moisture from the air under ambient conditions, or from substrates, especially organic substrates such as BT resins, printed circuit boards or polyimide flexible substrates. The adhesives also may contain a level of residual solvent or other volatiles.

At elevated attach temperatures, the absorbed moisture and residual volatile materials will evaporate rapidly. If this evaporation occurs faster than the vapors can diffuse out of the adhesive, voids or bubbles appear in the adhesive and can be a source of ultimate failure of the adhesive. This creates a need for curable compositions that are B-stageable but that do not promote voiding.

### SUMMARY OF THE INVENTION

This invention is an adhesive that comprises two chemical compositions have curing temperatures or curing temperature ranges sufficiently separated to allow the composition with the lower curing temperature, hereinafter the first composition, to cure without curing the composition with the higher curing temperature, hereinafter the second composition. In practice, the first composition will be cured during a B-staging process, and the second composition will be left uncured until a final cure is desired, such as, at the final attach of a semiconductor chip to a substrate. The fully cured material is cross-linked or polymerized to a sufficiently high molecular weight effective to give it structural integrity.

### DETAILED DESCRIPTION OF THE INVENTION

Each of the first and second composition is one or more monomeric, one or more oligomeric, or one or more polymeric compounds or resins, or combinations of those, that co-react to polymerize or cross-link. Both polymerization and cross-linking are referred to as curing. The compositions in general will contain a curing agent or curing initiator in addition to the monomeric, oligomeric, or polymeric species, and optionally, may contain a solvent. Within this specification and claims, the combination of the first and second compositions will be referred to as the total B-stageable adhesive.

The first composition will comprise a liquid, or a solid dissolved or dispersed in a solvent. The second composition will be a solid or semi-solid material at room temperature, dispersible or dissolvable either in the liquid first composition, or in the same or a compatible solvent for the first composition. The choice of first and second compositions will be determined in part by the temperature at which the final interconnection of the semiconductor chip to its substrate is made.

For example, if the final interconnect is made with tin-lead eutectic solder, the solder fluxing and interconnection occurs at a temperature of 183° C. The final curing of the adhesive should occur rapidly after the solder bump flow and interconnection and may occur at the solder reflow temperature or at a higher temperature. Consequently, in this case, the second composition will be chosen to have a curing temperature near or at 183° C. or slightly higher. If a polymeric interconnect material is used, the second composition will be chosen to have a curing temperature at or near the curing temperature of the polymeric interconnect. If wire-bonding is the final method of attach, the second composition will be chosen to have a curing temperature at or near the temperature for the wire-bonding.

The first composition is chosen so that it will cure before the curing temperature of the second composition and before the temperature at which the final interconnect of chip to substrate is made. The curing temperatures of the first and second compositions can be separated by any amount effective to provide two distinct curing profiles such that the second composition does not cure at the curing temperature or within the curing temperature range of the first composition. Insignificant curing of the second composition during the B-stage process is tolerable. In a preferred embodiment, the curing temperatures of the first and second compositions will be separated by at least 30° C.

Typically, the B-stage heating, that is, the first composition curing, occurs at a temperature within the range of about 100° C. to about 150° C. Any solvent used should be chosen to evaporate off within the same temperature range as first composition curing. Curing the first composition and evaporating the solvent during the B-stage process will solidify the total adhesive composition and inhibit voiding during the final attachment process because as a solid it will retain a high enough modulus or melt viscosity to constrain the bond-line and prevent the expansion of the vapor phase within the adhesive. After cure, the first composition must be capable of being tackified or softened at the final attach temperature for the semiconductor chip. The resultant cured material can be a linear, slightly branched, or lightly cross-linked polymer.

When heated to the appropriate attach temperature for the semiconductor die, the total adhesive composition should melt and flow sufficiently to completely wet-out the surface of the substrate. An efficient wet-out results in good adhesion.

The curing processes can be initiated and advanced by irradiation (such as with UV light) for the B-staging first cure, and then by heat for the final cure, or both the B-staging and final cure can be initiated and advanced by heat.

The first and second compositions will be present in a molar ratio of 5:95 to 95:5, as can be determined by the practitioner for specific end uses. Combinations of first compositions and second compositions of the total B-stageable adhesive include:

First: thermally curable acrylic compounds, such as those available from Sartomer, with free radical curing agents. Second: thermally curable epoxy compounds or resins, such as those available from National Starch, CIBA, Sumitomo or Dainippon, with latent amine or imidazole curing agents.

First: radiation curable cycloaliphatic epoxy compounds, such as CIBA CY179, with photoinitiators. Second: thermally curable aromatic epoxy compounds, such as bis-phenol A diepoxide, with phenolic hardeners and phosphine-based curing agents.

First: radiation curable acrylic compounds, such as those available from Sartomer, with photoinitiators. Second: thermally curable epoxy compounds, such as those available from National Starch, CIBA, Sumitomo or Dainippon, with latent amine or imidazole curing agents.

First: thermally initiated, free radical curable bismaleimide compounds (electron acceptors), such as those available from Ciba Specialty Chemicals or National Starch, with (electron donors) vinyl ethers, vinyl silanes, styrenic compounds, cinnamyl compounds. Second: thermally curable epoxy compounds, such as those available from National Starch, CIBA, Sumitomo or Dainippon with latent amine or imidazole curing agents.

In addition to the epoxies mentioned above, further examples of suitable epoxy resins include monofunctional and multifunctional glycidyl ethers of Bisphenol-A and Bisphenol-F, aliphatic and aromatic epoxies, saturated and unsaturated epoxies, cycloaliphatic epoxy resins and combinations of those. Bisphenol-A type resin is commercially available from Resolution Technology as EPON 828. Bisphenol F epoxy resin can be prepared by the reaction of one mole of bisphenol F resin and two moles of epichlorohydrin. Bisphenol-F type resins also are available commercially from CVC Specialty Chemicals, Maple Shade, N.J., under the designation 8230E, and from Resolution Performance Products LLC under the designation RSL1739. A blend of bisphenol-A and bisphenol-F is available from Nippon Chemical Company under the designation ZX-1059.

Another suitable epoxy resin is epoxy novolac resin, which is prepared by the reaction of phenolic resin and epichlorohydrin. A preferred epoxy novolac resin is poly(phenyl glycidyl ether)-co-formaldehyde. Other suitable epoxy resins are biphenyl epoxy resin, commonly prepared by the reaction of biphenyl resin and epichlorohydrin; dicyclopentadiene-phenol epoxy resin; naphthalene resins; epoxy functional butadiene acrylonitrile copolymers; epoxy functional polydimethyl siloxane; and mixtures of the above.

Non-glycidyl ether epoxides may also be used. Suitable examples include 3,4-epoxycyclohexylmethyl-3,4-epoxycyclohexane carboxylate, which contains two epoxide groups that are part of the ring structures and an ester linkage; vinylcyclohexene dioxide, which contains two epoxide groups and one of which is part of the ring structure; 3,4-epoxy-6-methyl cyclohexyl methyl-3,4-epoxycyclohexane carboxylate; and dicyclopentadiene dioxide.

Further examples of suitable epoxies include:

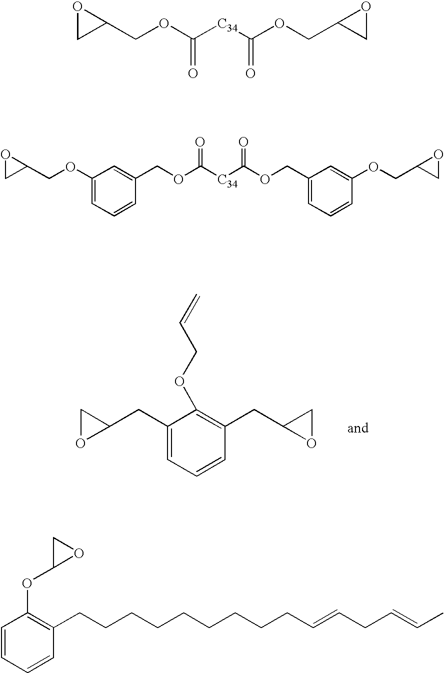

A suitable imidazole catalyst for epoxies, in addition to those commercially available, is an imidazole-anhydride adduct. Preferred imidazoles for forming the adduct include non-N-substituted imidazoles, such as, 2-phenyl-4-methyl imidazole, 2-phenyl imidazole, and imidazole. Other useful imidazole components for the adduct include alkyl-substituted imidazoles, N-substituted imidazoles, and mixtures of those.

Preferred anhydrides for forming the adduct are cycloaliphatic anhydrides, such as, pyromellitic dianhydride, commercially available as PMDA from Aldrich. Other suitable anhydrides include methylhexa-hydro phthalic anhydride (commercially available as MHHPA from Lonza Inc. Intermediates and Actives) methyltetra-hydrophthalic anhydride, nadic methyl anhydride, hexa-hydro phthalic anhydride, tetra-hydro phthalic anhydride, phthalic anhydride, dodecyl succinic anhydride, bisphenyl dianhydride, benzophenone tetracarboxylic dianhydride, and mixtures of those.

Two preferred adducts are a complex of 1 part 1,2,4,5-benzenetetracarboxylic anhydride and 4 parts 2-phenyl-4-methylimidazole, and a complex of 1 part 1,2,4,5-benzenetetracarboxylic dianhydride and 2 parts 2-phenyl-4-methylimidazole. The adducts are prepared by dissolving the components in a suitable solvent, such as acetone, under heat. Upon cooling the adduct precipitates out. Such adducts are used in any effective amount, but preferably are present in an amount of 1% to 20% by weight of the organic material in the composition.

Examples of suitable cinnamyl donors for use with maleimides include: 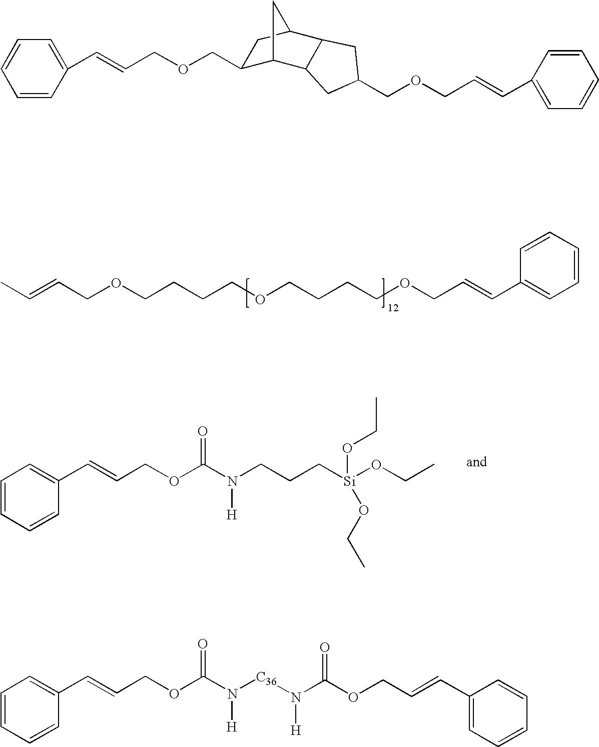
in which C₃₆ repreents a linear or branched alkyl of 36 carbons derived from linoleic and oleic acids.

Examples of suitable styrenic donors for use with maleimides include: 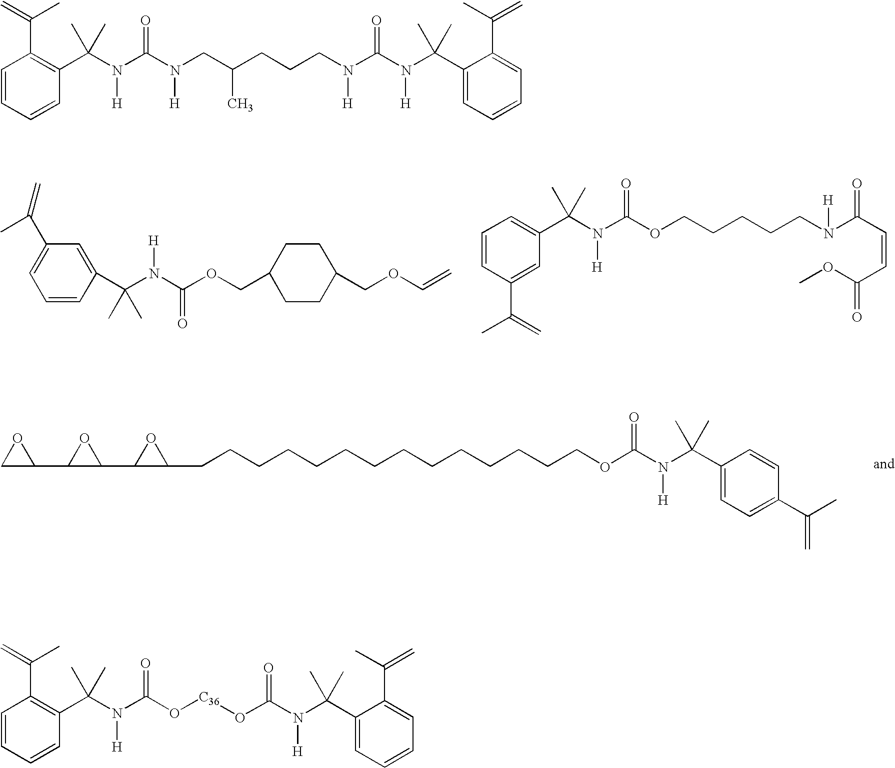
in which C₃₆ represents a linear or branched alkyl of 36 carbons derived from linoleic and oleic acids.

Curing agents such as free radical initiators, thermal initiators and photoinitiators will be present in an effective amount to cure the composition. In general, those amounts will range from 0.1% to 30%, preferably 1% to 20%, by weight of the total organic material (that is, excluding any inorganic fillers) in the composition. The actual cure profile will vary with the components and can be determined without undue experimentation by the practitioner.

The curable compositions may comprise nonconductive or thermally or electrically conductive fillers. Suitable nonconductive fillers are particles of vermiculite, mica, wollastonite, calcium carbonate, titania, sand, glass, fused silica, fumed silica, barium sulfate, and halogenated ethylene polymers, such as tetrafluoroethylene, trifluoro-ethylene, vinylidene fluoride, vinyl fluoride, vinylidene chloride, and vinyl chloride. Suitable conductive fillers are carbon black, graphite, gold, silver, copper, platinum, palladium, nickel, aluminum, silicon carbide, diamond, and alumina. If used, fillers generally will be present in amounts up to 98% by weight of the formulation.

Solvents can be utilized to modify the viscosity of the composition, and if used should be chosen so that they evaporate during the B-stage heating. Typically, B-stage heating will occur at temperatures lower than about 150° C. Examples of solvents that may be utilized include ketones, esters, alcohols, ethers, and other common solvents that are stable and dissolve the composition components. Preferred solvents include gamma-butyrolactone, carbitol acetate, acetone, methyl ethyl ketone, and propylene glycol methyl ethyl acetate.

In another embodiment, this invention is a method of attaching a semiconductor chip to a substrate comprising depositing onto the substrate a B-stageable curable composition comprising a first composition with a lower curing temperature as described previously, and a second composition with a higher curing temperature as described previously, heating the substrate and adhesive to the curing temperature of the first composition to cure that composition; contacting the adhesive with a semiconductor chip; and heating the substrate, adhesive, and semiconductor chip to the curing temperature of the second composition to cure that composition.

In a further embodiment, this invention is an assembly comprising a substrate for a semiconductor chip or die and a B-stageable adhesive deposited on the substrate, the B-stageable adhesive comprising a first composition with a lower curing temperature as described previously and a second composition with a higher curing temperature as described previously, characterized in that the first composition has been fully cured.

### EXAMPLES

A curable control formulation with one chemistry composition was prepared comprising a bis-phenol A epoxy, an elastomer, a phenolic hardener, and triphenyl phosphine as a catalyst, in carbitol acetate as the solvent.

Two curable inventive formulations, Formulation A and Formulation B, with both a first composition comprising a maleimide and a second composition comprising the epoxy composition of the control formulation were prepared in a weight ratio of about 1 to 10. The maleimide composition of Formulation A comprised a bis-maleimide, a mono-maleimide, a difunctional donor having the structure 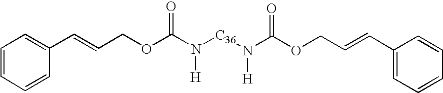
and a peroxide catalyst. The maleimide composition of Formulation B comprised a bis-maleimide, the difunctional donor shown above, and a peroxide catalyst.

The control and Formulations A and B were tested for Dynamic Tensile Modulus using a Rheometric Mk IV Mechanical Thermal Analyzer ramped from 25° C. to 300° C. at 3° C./min. The results are reported in the following table and show that the dual cure Formulations A and B have superior modulus at higher temperature than the control.

| Dynamic Tensile | | | |
|---|---|---|---|
| Modulus | Control | Formulation A | Formulation B |
| 25° C. | 1164 Mpa | 953 Mpa | 1080 Mpa |
| 150° C. | 3.6 Mpa | 19.6 Mpa | 53.0 Mpa |
| 250° C. | 1 Mpa | 9.7 Mpa | 15.2 Mpa |

The three formulations were tested for die shear strength. Each was dispensed onto an alumina plate and was heated to 120° C. for one hour (B-staged). This temperature was sufficient to evaporate off the solvent and to fully cure the maleimide in Formulations A and B. An alumina die, 80×80 mil, was placed onto the B-staged adhesive at 120° C. for one second using 500 g of force, and the formulation heated in an oven at 175° C. for 60 minutes to fully cure the epoxy. After cure, the die was sheared from the leadframe at 90 degrees with a Dage 2400-PC Die Shear Tester at 25° C. and at 245° C. The results are reported in the following table in Kg force and show that Formulations A and B with two different curing sets gave superior adhesive strength.

| Die Shear | | | |
|---|---|---|---|
| Strength | Control | Formulation A | Formulation B |
| 25° C. | 12.0 kg | 18.5 kg | 21.4 Kg |
| 245° C. | 0.8 kg | 2.9 kg | 3.1 kg |

The Control and Formulation A were tested further for die shear strength after conditioning in heat and humidity. Each was dispensed onto an alumina plate and heated for one hour at 120° C. (B-staged) to evaporate the solvent and to fully cure the maleimide in Formulation A. An alumina die, 80×80 mil, was placed onto the adhesive at 120° C. for one second using 500 g of force, and the formulation cured in an oven at 175° C. for 60 minutes to fully cure the epoxy. The cured assemblies were then subjected to 85° C./85% relative humidity for 48 hours, after which the die was sheared from the leadframe at 90 degrees with a Dage 2400-PC Die Shear Tester at 25° C. and at 245° C. The results are reported in the following table in Kg force and show that Formulation A gave superior results.

| Hot/Wet Die Shear Strength | Control | Formulation A |
|---|---|---|
| 25° C. | 7.4 kg | 14.1 kg |
| 245° C. | 0.8 kg | 1.9 kg |

The control and Formulations A and B were visually observed for voiding. Each formulation was dispensed on a bare (no solder mask) BT substrate and heated (B-staged) for one hour at 120° C. to evaporate the solvent and to fully cure the maleimide in Formulations A and B. A glass die 6 mm×11 mm was contacted with the formulation at 120° C. for one second with 500 g force. The assemblies were then heated for one hour at 175° C. to fully cure the epoxy. Each die and substrate assembly was inspected under a microscope for voiding. Approximately 5% of the surface area of the control formulation contained voids. For Formulations A and B, about one specimen in 10 contained a single void. This was deemed to be less than 1% voiding.

The formulations were tested further for moisture resistance. As in the test for voiding, each formulation was dispensed onto a bare (no solder mask) BT substrate and heated (B-staged) for one hour at 120° C. A glass die 6 mm×11 mm was contacted with the formulation at 120° C. for one second with 500 g force and the assemblies cured for one hour at 175° C. Each assembly was then conditioned at 85° C. and 60% relative humidity for 196 hours (JEDEC Level II), after which it was subjected to a simulated solder reflow temperature profile with a peak temperature of 260° C. and observed for delamination of the glass die from the substrate. (Solder reflow temperature is the temperature used to reflow solder in a process in which solder is used to attach a semiconductor chip to its substrate.) The assembly containing the control formulation delaminated in four out of 6 specimens. The assemblies adhered with Formulation A and Formulation B showed no delaminations out of 12 and 9 specimens respectively.

1-8. (canceled)

9. An assembly comprising a substrate for use within a semiconductor package and a B-stageable adhesive deposited on the substrate,
the B-stageable adhesive comprising two chemical compositions,
(i) a first composition comprising a curable monomeric or polymeric compound or resin and a curing initiator or curing agent for that compound or resin, and
(ii) a second composition comprising a monomeric or polymeric compound or resin and a curing initiator or curing agent for that compound or resin,
in which the curing temperatures or curing temperature ranges are sufficiently separated to allow the composition with the lower curing temperature, the first composition, to cure without curing the composition with the higher curing temperature, the second composition,
and characterized in that the first composition is fully cured and the second composition is uncured.

10. The assembly according to claim 9 in which the curing temperatures of the first and second compositions are separated by 30° C. or greater.

11. The assembly according to claim 9 in which the first composition is selected from the group consisting of acrylic compounds or resins; cycloaliphatic epoxy compounds or resins, bismaleimide compounds or resins; and bismaleimide compounds or resins in combination with vinyl ether, vinyl silane, styrenic or cinnamyl compounds or resins.

12. The assembly according to claim 9 in which the second composition is an epoxy compound or resin.

13. The assembly according to claim 13 further comprising an imidazole/anhydride adduct.

14. The assembly according to claim 14 in which the imidazole/anhydride adduct is a complex of 1 part 1,2,4,5-benzene-tetracarboxylic anhydride and 4 parts 2-phenyl-4-methyl-imidazole, or a complex of 1 part 1,2,4,5-benzenetetracarboxylic dianhydride and 2 parts 2-phenyl-4-methylimidazole.
